(19) United States
(12) Patent Application Publication
(10) Pub. No.: US 2024/0243161 A1
(43) Pub. Date: Jul. 18, 2024

(54) FRONTSIDE-ILLUMINATED IMAGE SENSOR

(71) Applicant: ENKRIS SEMICONDUCTOR, INC., Suzhou, Jiangsu (CN)

(72) Inventors: Yuchao Chen, Suzhou, Jiangsu (CN); Kai Cheng, Suzhou, Jiangsu (CN)

(73) Assignee: ENKRIS SEMICONDUCTOR, INC., Suzhou, Jiangsu (CN)

(21) Appl. No.: 18/556,836

(22) PCT Filed: Jun. 18, 2021
(86) PCT No.: PCT/CN2021/101075

§ 371 Date: Oct. 23, 2023

(51) Int. Cl. H01L 27/146

(52) U.S. Cl. CPC H01L 27/14652; H01L 27/14636; H01L 27/14647

(57) ABSTRACT

The present application provides a frontside-illuminated image sensor, including: a substrate, a photosensitive unit, and a lens structure. The substrate includes multiple charge storage regions. The photosensitive unit is on the substrate, where the photosensitive unit includes multiple photosensitive subunits, each of the multiple photosensitive subunits includes a red photosensitive layer, a green photosensitive layer, a blue photosensitive layer, and an infrared photosensitive layer) that are stacked, and the multiple photosensitive subunits are respectively electrically connected to the multiple charge storage regions. The lens structure is on a side of the photosensitive unit far from the substrate.

### CROSS-REFERENCE TO RELATED APPLICATIONS

This application is a national stage entry of, and claims priority to, International Patent Application No. PCT/CN2021/101075 (filed 18 Jun. 2021), the entire disclosure of which is incorporated herein by reference.

### TECHNICAL FIELD

The present disclosure relates to the technical field of semiconductors, and in particular, to a frontside-illuminated image sensor.

### BACKGROUND

Image sensors utilize photoelectric conversion to convert a light image on a photosurface into electrical signals proportional to the light image. Compared with photosensitive components of point light sources such as photodiodes and phototransistors, image sensors are functional devices that divide the light image on their photosurface into many small units and convert them into usable electrical signals. Image sensors are divided into photoconductive camera tubes and solid-state image sensors. Compared with photoconductive camera tubes, solid-state image sensors have the characteristics of small size, light weight, high integration, high resolution, low power consumption, long lifespan, and low price, which makes them widely used in various industries.

Currently, most color image sensors use backside-illuminated CMOS structure. The shortcomings of a backside-illuminated color image sensor are: first, it is necessary to manufacture a photodiode and an electrical interconnecting structure for photoelectric conversion on a front of a silicon wafer, and to manufacture a filter structure and a lens on a back of a silicon wafer. The process is complex and the front photodiode needs to be aligned with the back filter structure and lens, which will result in low yield of the backside-illuminated image sensor: second, the photodiode occupies a large area, which makes a space for a charge storage region and storage capacitor more limited, increasing the difficulty of capacitor design for high-dynamic range (HDR) performance and global shutter: third, during the process of light propagation to a photodiode in a silicon wafer, there is significant interference, and a deep groove isolation structure needs to be manufactured to separate the light propagating to adjacent photodiodes, which is a complex process.

In addition, in photodiodes, as the dynamic range requirements increase and global shutter applications become popular, the requirements for larger full well capacity and larger storage capacitor are becoming increasingly high. At present, the solutions on the market mainly focus on redesigning photodiodes and storage capacitors and modifying the circuit to match them, which does not substantially change the total storage space and increases the difficulty of circuit design, and the requirement of backside-illuminated CMOS structure further increases the difficulty of the process.

Furthermore, the current near-infrared image sensors are front-illuminated, and in order to isolate substrate noise and metal pollution, SOI (Silicon-On-Insulator) substrates are required, which is costly. Near-infrared image sensors and color image sensors need to be manufactured separately. When in use, switching between color sensors and near-infrared image sensors often involves switching between infrared filters or sensors, which greatly increases costs and also affects the product's lifespan and maintenance costs.

### SUMMARY

The purpose of the present disclosure is to provide a frontside-illuminated image sensor to address the shortcomings in related technologies.

To achieve the above purpose, the present disclosure provides a frontside-illuminated image sensor, including:
a substrate with multiple charge storage regions:
a photosensitive unit on the substrate, where the photosensitive unit includes multiple photosensitive subunits, each of the multiple photosensitive subunits includes a red photosensitive layer, a green photosensitive layer, a blue photosensitive layer, and an infrared photosensitive layer) that are stacked, and the multiple photosensitive subunits are respectively electrically connected to the multiple charge storage regions: and
a lens structure on a side of the photosensitive unit far from the substrate.

In some embodiments, materials of the red photosensitive layer, the green photosensitive layer, and the blue photosensitive layer include GaN-based materials containing In element, and proportions of In components in the red photosensitive layer, the green photosensitive layer, and the blue photosensitive layer are different, to generate photosensitive charges based on wavelengths of received light and store the photosensitive charges in a corresponding charge storage region or not generate photosensitive charges based on the wavelengths of the received light.

In some embodiments, a range of the proportion of In component in the red photosensitive layer is from 0.4 to 0.6; and
a range of the proportion of In component in the green photosensitive layer is from 0.2 to 0.3;
a range of the proportion of In component in the blue photosensitive layer is from 0.01 to 0.1: and
a range of the proportion of In component in the infrared photosensitive layer is from 0.7 to 0.9.

In some embodiments, in a direction away from the substrate, each of the multiple photosensitive subunits sequentially includes the blue photosensitive layer, the green photosensitive layer, the red photosensitive layer, and the infrared photosensitive layer.

In some embodiments, the frontside-illuminated image sensor further includes: multiple transistors on the substrate, and a source region or a drain region of at least one of the multiple transistors is one of the multiple charge storage regions: and a metal interconnecting layer between the substrate and the photosensitive unit, where a metal interconnecting structure of the metal interconnecting layer is configured to electrically connect the multiple transistors.

In some embodiments, at least one of the multiple transistors is provided with a photosensitive processing circuit, and the photosensitive processing circuit is configured to detect photosensitive electrical signal(s) generated by the photosensitive subunit; where
in response to determining that a photosensitive electrical signal intensity detected by the photosensitive processing circuit from the photosensitive subunit is greater than a first threshold, a blue-light incident signal is stored;
in response to determining that a photosensitive electrical signal intensity detected by the photosensitive processing circuit from the photosensitive subunit is greater than a second threshold and less than or equal to the first threshold, a green-light incident signal is stored;
in response to determining that a photosensitive electrical signal intensity detected by the photosensitive processing circuit from the photosensitive subunit is greater than a third threshold and less than or equal to the second threshold, a red-light incident signal is stored;
in response to determining that a photosensitive electrical signal intensity detected by the photosensitive processing circuit from the photosensitive subunit is less than or equal to the third threshold, an infrared-light incident signal is stored.

In some embodiments, the frontside-illuminated image sensor further includes a conductive plug in the metal interconnecting layer, where a first end of the conductive plug is connected to one of the multiple photosensitive subunits, and a second end of the conductive plug is electrically connected to one of the multiple charge storage regions.

In some embodiments, the second end of the conductive plug is connected to a side wall of one of the multiple photosensitive subunits.

In some embodiments, the frontside-illuminated image sensor further includes a light blocking structure between adjacent photosensitive subunits of the multiple photosensitive subunits.

In some embodiments, a material of the light blocking structure includes molybdenum, an alloy of molybdenum, aluminum, or an alloy of aluminum.

### BRIEF DESCRIPTION OF DRAWINGS

FIG. 1 is a cross-sectional structural diagram of a frontside-illuminated image sensor of a first embodiment of the present disclosure.

FIG. 2 is a cross-sectional structural diagram of a frontside-illuminated image sensor of a second embodiment of the present disclosure.

FIG. 3 is a cross-sectional structural diagram of a frontside-illuminated image sensor of a third embodiment of the present disclosure.

FIG. 4 is a cross-sectional structural diagram of a frontside-illuminated image sensor of a fourth embodiment of the present disclosure.

For the convenience of understanding the present disclosure, all reference numerals appearing in the present disclosure are listed below.

| | |
|---|---|
| frontside-illuminated image | base 10 |
| sensors 1, 2, 3, 4 | photosensitive unit 11 |
| charge storage region 101 | green photosensitive |
| red photosensitive | layer 111b |
| layer 111a | infrared photosensitive |
| blue photosensitive | layer 111d |
| layer 111c | lens structure 12 |
| photosensitive subunit 111 | photosensitive processing |
| light blocking structure 112 | circuit 13 |
| transistor 102 | metal interconnecting |
| metal interconnecting | layer 14 |
| structure 141 | conductive plug 142 |

### DETAILED DESCRIPTION

In order to make the above-mentioned objects, features and advantages of the present disclosure more obvious and understandable, embodiments of the present disclosure will be described in detail below with reference to the accompanying drawings.

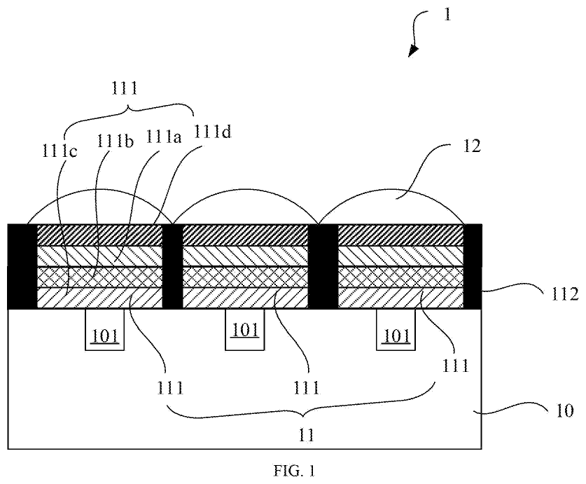

FIG. 1 is a cross-sectional structural diagram of a frontside-illuminated image sensor of a first embodiment of the present disclosure.

As shown in FIG. 1, a frontside-illuminated image sensor 1 includes:
a substrate 10 with multiple charge storage regions 101;
a photosensitive unit 11 on the substrate 10, where the photosensitive unit 11 includes multiple photosensitive subunits 111, each of the multiple photosensitive subunits 111 includes a red photosensitive layer 111a, a green photosensitive layer 111b, a blue photosensitive layer 111c, and an infrared photosensitive layer 111d that are stacked, and one photosensitive subunit 111 is electrically connected to one charge storage region 101: and
a lens structure 12 on a side of the photosensitive unit 11 far from the substrate 10.

The substrate 10 can include a monocrystalline silicon substrate. The charge storage region 101 can be a floating diffusion (FD) region, for example, an n-type lightly doped region formed in a p-type well can serve as a floating diffusion region.

Materials of the red photosensitive layer 111a, the green photosensitive layer 111b, the blue photosensitive layer 111c, and the infrared photosensitive layer 111d include GaN-based materials containing In element, and proportions of In components in the red photosensitive layer 111a, the green photosensitive layer 111b, the blue photosensitive layer 111c, and the infrared photosensitive layer 111d are different, to generate photosensitive charges based on wavelengths of received light and store the photosensitive charges in a corresponding charge storage region 101 or not generate photosensitive charges based on wavelengths of received light.

The proportion of In component in the infrared photosensitive layer 111d can be greater than the proportion of In component in the red photosensitive layer 111a, the proportion of In component in the red photosensitive layer 111a can be greater than the proportion of In component in the green photosensitive layer 111b, and the proportion of In component in the green photosensitive layer 111b can be greater than the proportion of In component in the blue photosensitive layer 111c.

A range of the proportion of In component in the red photosensitive layer 111a can be from 0.4 to 0.6, and a range of wavelength of light required to generate photosensitive current can be from 400 nm to 720 nm.

A range of the proportion of In component in the green photosensitive layer 111b can be from 0.2 to 0.3, and a range of wavelength of light required to generate photosensitive current can be from 400 nm to 600 nm.

A range of the proportion of In component in the blue photosensitive layer 111c can be from 0.01 to 0.1, and a range of wavelength of light required to generate photosensitive current can be from 400 nm to 500 nm.

A range of the proportion of In component in the infrared photosensitive layer 111d can be from 0.7 to 0.9, and a range of wavelength of light required to generate photosensitive current can be from 800 nm to 950 nm.

It should be noted that the proportion of In component in the red photosensitive layer 111a refers to a percentage of the amount of substance of In element in the amount of substance of all positively charged elements in the red photosensitive layer 111a. For example, the material of the red photosensitive layer 111a is InGaN, and the proportion of In component refers to the percentage of the amount of substance of In element in the sum of the amount of substance of In element and the amount of substance of Ga element. For example, the material of the red photosensitive layer 111a is InAlGaN, and the proportion of In component refers to the percentage of the amount of substance of In element in the sum of the amount of substance of In element, the amount of substance of Al element, and the amount of substance of Ga element.

The proportion of In component in the green photosensitive layer 111b refers to a percentage of the amount of substance of In element in the amount of substance of all positively charged elements in the green photosensitive layer 111b.

The proportion of In component in the blue photosensitive layer 111c refers to a percentage of the amount of substance of In element in the amount of substance of all positively charged elements in the blue photosensitive layer 111c.

The proportion of In component in the infrared photosensitive layer 111d refers to a percentage of the amount of substance of In element in the amount of substance of all positively charged elements in the infrared photosensitive layer 111d.

In addition, in this embodiment, each numerical range includes the endpoint value.

In this way, for each photosensitive subunit 111, if blue light is irradiated, the red photosensitive layer 111a, green photosensitive layer 111b, blue photosensitive layer 111c, and infrared photosensitive layer 111d can all generate photosensitive electrical signals. If green light is illuminated, the red photosensitive layer 111a, green photosensitive layer 111b, and infrared photosensitive layer 111d can generate photosensitive electrical signals. If red light is illuminated, the red photosensitive layer 111a and the infrared photosensitive layer 111d can generate photosensitive electrical signals. If infrared light is illuminated, only the infrared photosensitive layer 111d can generate a photosensitive electrical signal. In other words, for the same photosensitive subunit 111, the photosensitive electrical signal intensity generated by blue light irradiation is greater than the photosensitive electrical signal intensity generated by green light irradiation. The photosensitive electrical signal intensity generated by green light irradiation is greater than the photosensitive electrical signal intensity generated by red light irradiation, and the photosensitive electrical signal intensity generated by red light irradiation is greater than the photosensitive electrical signal intensity generated by infrared light irradiation. Therefore, even if a structure of each photosensitive subunit 111 is the same, the color and brightness of the illuminated light can still be distinguished by the intensity of the photosensitive signal.

In some embodiments, in a direction away from the substrate 10, each of the multiple photosensitive subunits 111 sequentially includes the blue photosensitive layer 111c, the green photosensitive layer 111b, the red photosensitive layer 111a, and the infrared photosensitive layer 111d. One of the advantages of the above setting manner is that it can prevent infrared and red light from decaying too quickly when passing through various photosensitive layers.

The lens structure 12 includes multiple lenses, with one lens located above each photosensitive subunit 111.

In addition, in this embodiment, there is a light blocking structure 112 between adjacent photosensitive units 111. Before epitaxial growth of blue photosensitive layer 111c, green photosensitive layer 111b, red photosensitive layer 111a, and infrared photosensitive layer 111d on the substrate 10, multiple light blocking structures 112 can be formed on the substrate 10.

The material of the light blocking structure 112 can include molybdenum, an alloy of molybdenum, aluminum, or an alloy of aluminum. To prevent interference between adjacent photosensitive layers, insulated spacers can be provided on the side walls of the light blocking structure 112. The material of the insulated spacer can include silicon nitride or silicon dioxide.

In this embodiment, first, the image sensor is a frontside-illuminated image sensor 1, which can avoid manufacturing a structure on the back of the substrate 10, thus avoiding alignment between a front structure and a back structure. The process is simple, and the yield is high: second, one photosensitive subunit 111 is electrically connected to a charge storage region 101, which greatly reduces interference caused by light propagation: and third, the photosensitive unit 11 not only includes a visible-light photosensitive layer, but also an infrared-light photosensitive layer 111d, which can sense visible and infrared light according to the wavelength of the irradiated light. It integrates color image sensors and infrared image sensors, which has high integration and low cost.

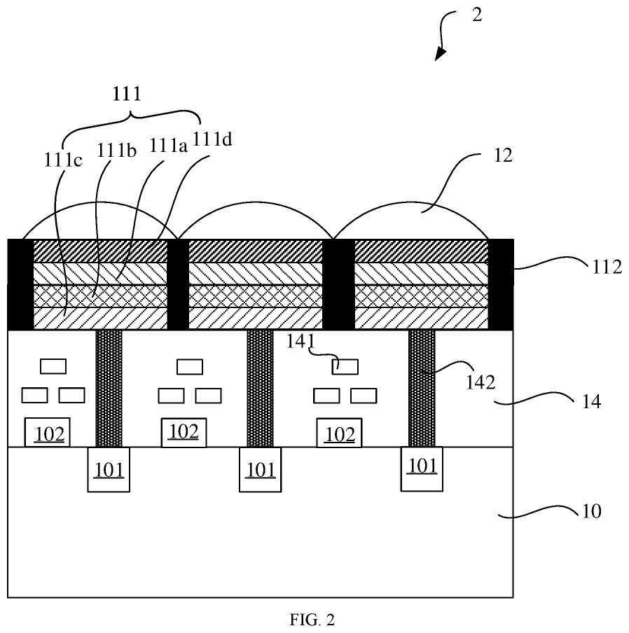

FIG. 2 is a cross-sectional structural diagram of a frontside-illuminated image sensor of a second embodiment of the present disclosure.

As shown in FIG. 2 and FIG. 1, a frontside-illuminated image sensor 2 of the second embodiment is roughly the same as the frontside-illuminated image sensor 1 of the first embodiment, except that there are multiple transistors 102 on the substrate 10, and a source region or a drain region of at least one of the multiple transistors 102 is one of the multiple charge storage regions 101: and there is a metal interconnecting layer 14 between the substrate 10) and the photosensitive unit 11, where a metal interconnecting structure 141 of the metal interconnecting layer 14 is configured to electrically connect the multiple transistors 102.

The transistor 102 can include a transfer transistor, a reset transistor, a source follower transistor, and a row selection transistor. The source electrode of the transfer transistor is electrically connected to a color sensitive layer through a metal interconnecting structure 141, and the drain electrode of the transfer transistor is a floating diffusion region. Therefore, the transfer transistor is used to transfer photoelectric charges from a color sensitive layer to a floating diffusion region. The source electrode of the reset transistor is a floating diffusion region, and the drain electrode of the reset transistor is electrically connected to a power supply voltage line through a metal interconnecting structure 141. Therefore, the reset transistor is used to reset the floating diffusion region to the VDD (Voltage Drain Drain). Through the metal interconnecting structure 141, the gate electrode of the source follower transistor is electrically connected to the floating diffusion region, the source electrode of the source follower transistor is electrically connected to the VDD, and the drain electrode of the source follower transistor is electrically connected to the source electrode of the row selection transistor. Through the metal interconnecting structure 141, the gate electrode of the row selection transistor is electrically connected to the row scanning line for outputting the drain voltage of the source follower transistor in response to the address signal. The source and drain electrodes mentioned above can be exchanged according to the current flow direction.

In addition, as shown in FIG. 2, there is a conductive plug 142 in the metal interconnecting layer 14, where a first end of the conductive plug 142 is connected to one of the multiple photosensitive subunits 111, and a second end of the conductive plug 142 is electrically connected to one of the multiple charge storage regions 101. Moreover, the first end of the conductive plug 142 is connected to the bottom wall of a photosensitive subunit 111.

In the second embodiment, the photosensitive unit 11 is located above the substrate 10 rather than on the surface of the substrate 10, so the space for the charge storage region and storage capacitor can be designed to be large enough to obtain a larger full well capacity, which can bring about an improvement in high dynamic range, and naturally have the design conditions of a global shutter.

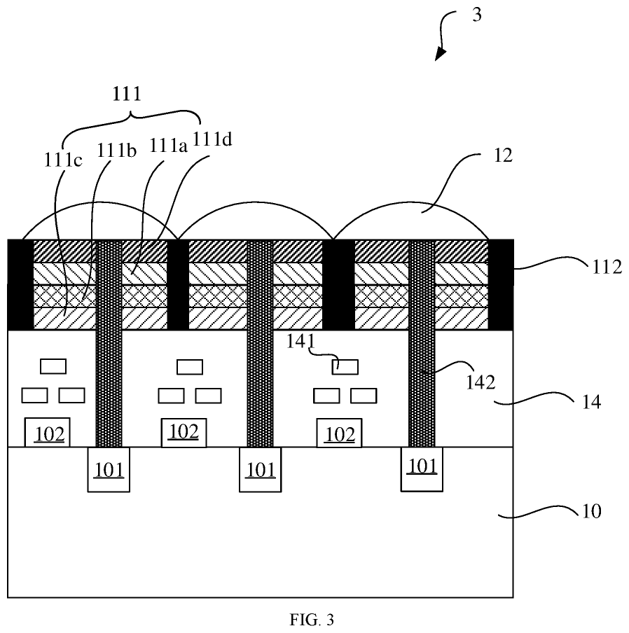

FIG. 3 is a cross-sectional structural diagram of a frontside-illuminated image sensor of a third embodiment of the present disclosure.

As shown in FIG. 2 and FIG. 3, a frontside-illuminated image sensor 3 of the third embodiment is roughly the same as the frontside-illuminated image sensor 2 of the second embodiment, except that the first end of the conductive plug 142 is connected to a side wall of one of the multiple photosensitive subunits 111. Research has shown that for the GaN-based material photosensitive layer containing In element, the current flowing in the plane is greater than the current flowing in the thickness direction. Therefore, the conductive plug 142 connected to the side wall of each photosensitive layer can increase the amount of transferred photoelectric charges.

In some embodiments, the side wall of the photosensitive subunit 111 connected to the first end of the conductive plug 142 is close to the light blocking structure 112.

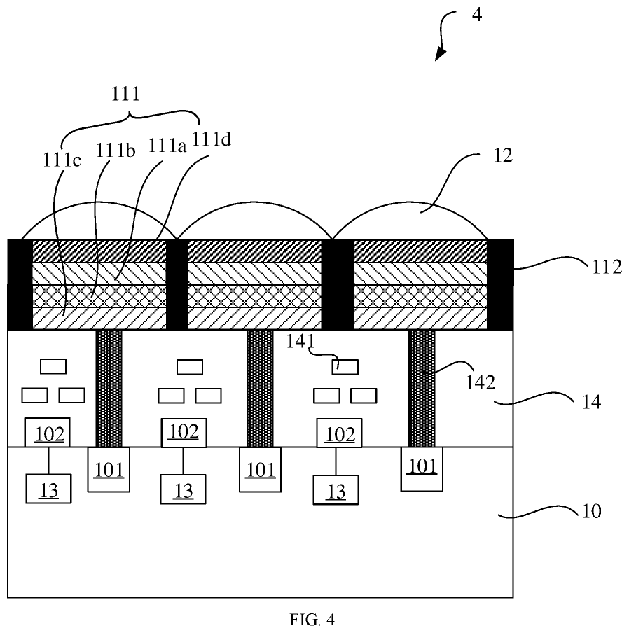

FIG. 4 is a cross-sectional structural diagram of a frontside-illuminated image sensor of a fourth embodiment of the present disclosure.

As shown in FIGS. 4, 3, and 2, a frontside-illuminated image sensor 4 of the fourth embodiment is roughly the same as the frontside-illuminated image sensors 2 and 3 of the second and third embodiments, except that:
some of the multiple transistors 102 are provided with photosensitive processing circuits 13, and the photosensitive processing circuits 13 are configured to detect photosensitive electrical signals generated by the multiple photosensitive subunits 111;
in response to determining that a photosensitive electrical signal intensity detected by the photosensitive processing circuit 13 from the photosensitive subunit 111 is greater than a first threshold, a blue-light incident signal is stored;
in response to determining that a photosensitive electrical signal intensity detected by the photosensitive processing circuit 13 from the photosensitive subunit 111 is greater than a second threshold and less than or equal to the first threshold, a green-light incident signal is stored;
in response to determining that a photosensitive electrical signal intensity detected by the photosensitive processing circuit 13 from the photosensitive subunit 111 is greater than a third threshold and less than or equal to the second threshold, a red-light incident signal is stored;
in response to determining that a photosensitive electrical signal intensity detected by the photosensitive processing circuit 13 from the photosensitive subunit 111 is less than or equal to the third threshold, an infrared-light incident signal is stored.

The first threshold is greater than the second threshold, and the second threshold is greater than the third threshold.

The drain electrode of the row selection transistor can be connected to the input end of the photosensitive processing circuit 13.

Compared with the prior art, the present disclosure has the following beneficial effects:

First, the photosensitive unit is located above the substrate, and the lens structure is located on a side of the photosensitive unit far from the substrate. In other words, the image sensor is a frontside-illuminated image sensor, which avoids manufacturing a structure on a back of the substrate, thus avoiding alignment between a front structure and a back structure. The process is simple, and the yield is high. Second, the photosensitive unit is located above the substrate rather than on the surface of the substrate, so the space for the charge storage region and storage capacitor can be designed to be large enough to obtain a larger full well capacity, which can bring about an improvement in high dynamic range, and naturally have the design conditions of a global shutter. Third, a photosensitive subunit is electrically connected to a charge storage region, which greatly reduces interference caused by light propagation. Fourth, the photosensitive subunit not only includes visible-light photosensitive layers, but also an infrared photosensitive layer. The photosensitive subunit can sense visible and infrared light according to wavelengths of the light. A color image sensor and an infrared image sensor are integrated, which has high integration and low cost.

Although the present disclosure is disclosed as above, the present disclosure is not limited thereto. Any person skilled in the art can make various changes and modifications without departing from the spirit and scope of the present disclosure, and therefore the scope of protection of the present disclosure shall be subject to the scope defined by the claims.

1. A frontside-illuminated image sensor, comprising:
a substrate with multiple charge storage regions;
a photosensitive unit on the substrate, wherein the photosensitive unit comprises multiple photosensitive subunits, each of the multiple photosensitive subunits comprises a red photosensitive layer, a green photosensitive layer, a blue photosensitive layer, and an infrared photosensitive layer that are stacked, and the multiple photosensitive subunits are respectively electrically connected to the multiple charge storage regions; and
a lens structure on a side of the photosensitive unit far from the substrate.

2. The frontside-illuminated image sensor according to claim 1, wherein materials of the red photosensitive layer, the green photosensitive layer, the blue photosensitive layer, and the infrared photosensitive layer comprise GaN-based materials containing In element, and proportions of In components in the red photosensitive layer, the green photosensitive layer, the blue photosensitive layer, and the infrared photosensitive layer are different, to generate photosensitive charges based on wavelengths of received light and store the photosensitive charges in a corresponding charge storage region or not generate photosensitive charges based on the wavelengths of the received light.

3. The frontside-illuminated image sensor according to claim 2, wherein a range of the proportion of In component in the red photosensitive layer is from 0.4 to 0.6;
a range of the proportion of In component in the green photosensitive layer is from 0.2 to 0.3;
a range of the proportion of In component in the blue photosensitive layer is from 0.01 to 0.1; and
a range of the proportion of In component in the infrared photosensitive layer is from 0.7 to 0.9.

4. The frontside-illuminated image sensor according to claim 1, wherein in a direction away from the substrate, each of the multiple photosensitive subunits sequentially comprises the blue photosensitive layer, the green photosensitive layer-, the red photosensitive layer-, and the infrared photosensitive layer.

5. The frontside-illuminated image sensor according to claim 1, further comprising:
multiple transistors on the substrate, and a source region or a drain region of at least one of the multiple transistors is one of the multiple charge storage regions; and
a metal interconnecting layer between the substrate and the photosensitive unit, wherein a metal interconnecting structure of the metal interconnecting layer is configured to electrically connect the multiple transistors.

6. The frontside-illuminated image sensor according to claim 5, wherein at least one of the multiple transistors is provided with a photosensitive processing circuit-, and the photosensitive processing circuit is configured to detect a photosensitive electrical signal generated by the photosensitive subunit; wherein
in response to determining that a photosensitive electrical signal intensity detected by the photosensitive processing circuit from the photosensitive subunit is greater than a first threshold, a blue-light incident signal is stored;
in response to determining that a photosensitive electrical signal intensity detected by the photosensitive processing circuit from the photosensitive subunit is greater than a second threshold and less than or equal to the first threshold, a green-light incident signal is stored;
in response to determining that a photosensitive electrical signal intensity detected by the photosensitive processing circuit from the photosensitive subunit is greater than a third threshold and less than or equal to the second threshold, a red-light incident signal is stored; and
in response to determining that a photosensitive electrical signal intensity detected by the photosensitive processing circuit from the photosensitive subunit is less than or equal to the third threshold, an infrared-light incident signal is stored.

7. The frontside-illuminated image sensor according to claim 5, further comprising:
a conductive plug in the metal interconnecting layer, wherein a first end of the conductive plug is connected to one of the multiple photosensitive subunits, and a second end of the conductive plug is electrically connected to one of the multiple charge storage regions.

8. The frontside-illuminated image sensor according to claim 7, wherein the first end of the conductive plug is connected to a side wall of one of the multiple photosensitive subunits.

9. The frontside-illuminated image sensor according to claim 1, further comprising:
a light blocking structure between adjacent photosensitive subunits of the multiple photosensitive subunits.

10. The frontside-illuminated image sensor according to claim 9, wherein a material of the light blocking structure comprises molybdenum, an alloy of molybdenum, aluminum, or an alloy of aluminum.

11. The frontside-illuminated image sensor according to claim 1, wherein, the substrate comprises a monocrystalline silicon substrate, one of the multiple charge storage regions is a floating diffusion region, wherein the floating diffusion region is an n-type lightly doped region formed in a p-type well.
